(19) United States
(12) Patent Application Publication
(10) Pub. No.: US 2021/0151701 A1
(43) Pub. Date: May 20, 2021

(54) HIGHLY EFFICIENT PEROVSKITE/Cu(In, Ga)Se2 TANDEM SOLAR CELL

(71) Applicant: The Regents of the University of California, Oakland, CA (US)

(72) Inventors: Yang YANG, Los Angeles, CA (US); Qifeng HAN, Los Angeles, CA (US); Yao-Tsung HSIEH, Los Angeles, CA (US)

(73) Assignee: The Regents of the University of California, Oakland, CA (US)

(21) Appl. No.: 17/047,045

(22) PCT Filed: Apr. 12, 2019
(86) PCT No.: PCT/US19/27336

§ 371 Date: Oct. 12, 2020

Related U.S. Application Data
(60) Provisional application No. 62/656,703, filed on Apr. 12, 2018.

(51) Int. Cl. H01L 51/44; H01L 51/42

(52) U.S. Cl. CPC H01L 51/447; H01L 51/0097; H01L 51/4213

(57) ABSTRACT

A monolithic tandem photovoltaic cell includes a first electrode; a CIGS light absorption section on the first electrode; an interconnecting layer on the CIGS light absorption section; and a perovskite light absorption section on the inter-connecting layer. The interconnecting layer has a polished surface on which the perovskite light absorption section is formed. The interconnecting layer provides an electrically conducting and optically transparent connection between the CIGS light absorption section and the perovskite light absorption section.

### CROSS-REFERENCE TO RELATED APPLICATIONS

The present patent application claims priority benefit to U.S. Provisional Patent Application No. 62/656,703 filed on Apr. 12, 2018, the entire content of which is incorporated herein by reference. All references cited anywhere in this specification, including the Background and Detailed Description sections, are incorporated by reference as if each had been individually incorporated.

### STATEMENT REGARDING FEDERALLY SPONSORED RESEARCH OR DEVELOPMENT

This invention was made with government support under Grant Number ECCS-1509955 awarded by the National Science Foundation. The government has certain rights in the invention.

### BACKGROUND

### 1. Technical Field

The field of the currently claimed embodiments of this invention relates to photovoltaic cells, and more particularly to monolithic tandem photovoltaic cells and their method of production.

### 2. Discussion of Related Art

In the following paragraphs some technical terms are used. The technical terms are defined for clarity.

The term “CIGS light absorption material” stands for CuInₓGa₍₁₋ₓ₎Se₂, where x is less than one (“1”) and greater than zero (“0”).

The term “perovskite (PVSK) light absorption material” refers to a light absorption material that has a structure of ABX₃, where ‘A’ and ‘B’ are two cations of very different sizes, and X is an anion that bonds to both.

PTAA is an acronym for Poly[bis(4-phenyl)(2,4,6-trimethylphenyl)amine, one of the family members of poly(triaryl)amine.

The abundance of solar radiation presents an enormous incentive to develop methods to harness its energy. Compared to current means of obtaining energy, the major challenge lies not in the availability but in the harvesting and storing of the sun's energy in a cost-effective and environmental-friendly manner. The key to achieving affordable photovoltaic (PV) technologies is to develop techniques that offer both high performance and low material and processing costs. Although silicon-based solar panels remain the dominant market share with steadily growing power conversion efficiencies (PCE) and reducing costs, their efficiencies and practicality remain inferior to other forms of power generation. On the other hand, thin film solar cells are becoming a promising alternative due to their low cost and low energy usage during manufacturing. To further improve the cost-effectiveness of thin film solar cells, it is necessary to improve efficiencies while simultaneously reducing costs.

In an effort to boost efficiencies, multi junction solar cells have been developed that connect multiple sub-cells in series to cover a broader range of the spectrum and combine attributes from each cell design. Reducing thermalization losses of hot carriers generated by photons with larger energies than the bandgap (Eg) can break the limit of the theoretical maximum efficiency for a single junction photovoltaic cell. Multi junction cells reduce this loss dramatically by combining several photovoltaic units with cascading Eg values in a tandem structure. However, the cost to fabricate efficient tandem solar cells is often quite high. To date, over 30% efficient epitaxial III-V solar cells have been achieved, however, high fabrication costs restrict the wide adoption of these technologies.

Therefore, an over 30% efficient, low-cost solar cell is a commercially unmet need. Therefore, there remains a need for improved photovoltaic cells.

### SUMMARY

An aspect of the present invention is to provide a monolithic tandem photovoltaic cell. The monolithic tandem photovoltaic cell includes a first electrode; a CIGS light absorption section on the first electrode; an interconnecting layer on the CIGS light absorption section; and a perovskite light absorption section on the inter-connecting layer. The interconnecting layer has a polished surface on which the perovskite light absorption section is formed. The interconnecting layer provides an electrically conducting and optically transparent connection between the CIGS light absorption section and the perovskite light absorption section.

Another aspect of the present invention is to provide a method of producing a monolithic tandem photovoltaic cell. The method includes providing a first electrode on a substrate; producing a CIGS light absorption section on the first electrode; depositing an interconnecting layer on the CIGS light absorption section; polishing the interconnecting layer; and producing a perovskite light absorption section on the inter-connecting layer. The interconnecting layer provides an electrically conducting and optically transparent connection between the CIGS light absorption section and the perovskite light absorption section.

### BRIEF DESCRIPTION OF THE DRAWINGS

The present disclosure, as well as the methods of operation and functions of the related elements of structure and the combination of parts and economies of manufacture, will become more apparent upon consideration of the following description and the appended claims with reference to the accompanying drawings, all of which form a part of this specification, wherein like reference numerals designate corresponding parts in the various figures. It is to be expressly understood, however, that the drawings are for the purpose of illustration and description only and are not intended as a definition of the limits of the invention.

FIG. 1A is a scanning electron microscope (SEM) image of a CIGS surface before chemical mechanical polishing (CMP), according to an embodiment of the present invention;

FIG. 1B is an atomic force microscope (AFM) image of the CIGS surface before CMP, according to an embodiment of the present invention;

FIG. 1C is a SEM image of an ITO/AZO bilayer surface after CMP polishing, according to an embodiment of the present invention;

FIG. 1D is an AFM image of the ITO/AZO bilayer surface after CMP polishing, according to an embodiment of the present invention;

FIG. 1E is a SEM image of an AZO surface after CMP polishing, according to an embodiment of the present invention;

FIG. 1F is an AFM image of the AZO surface after CMP polishing, according to an embodiment of the present invention;

FIG. 2 is a plot of current density per surface area J_{SC} (in mA/cm²) versus voltage showing the curves of CIGS solar cells with as-deposited ITO and after ITO polishing, according to an embodiment of the present invention;

FIG. 3 is a schematic three-dimensional representation of the semi-transparent single-junction perovskite (PVSK) solar cell, according to an embodiment of the present invention;

FIG. 4 is a schematic three-dimensional representation of the semi-transparent PVSK/CIGS tandem solar cell, according to an embodiment of the present invention;

FIG. 5 is a plot of the current density J_{SC} (in mA/cm²) versus the voltage applied showing the current density-voltage curve (NREL-certified) and the efficiency at the maximum power point (inset) of the PVSK/CIGS tandem device, according to an embodiment of the present invention;

FIG. 6A is an atomic force microscope image of the CIGS surface prior to CMP polishing, according to an embodiment of the invention;

FIG. 6B is an atomic force microscope image of the CIGS surface after CMP polishing, according to an embodiment of the present invention;

FIG. 6C shows a process diagram of various steps of fabrication of the device and cross-section SEM images of the CMP processing on the CIGS surface, according to an embodiment of the present invention;

FIG. 6D is a graph of the current-density versus voltage of the original CIGS solar cell and after CMP polishing with a step size of 0.02 V and a scan velocity of 0.1 V/s, according to an embodiment of the present invention;

FIG. 6E is plot of external quantum efficiency (EQE) versus wavelength of radiation or illumination incident on the device showing a difference between the original CIGS and the CIGS after polishing, according to an embodiment of the present invention;

FIG. 7A is a three-dimensional schematic representation of a semitransparent perovskite solar cell with inverted structure (i.e., p-i-n), according to an embodiment of the present invention;

FIG. 7B shows the optical transmittance of the semitransparent perovskite single junction cell, according to an embodiment of the present invention;

FIG. 7C is a plot of the current density versus voltage (J-V) of semitransparent devices using F4-TCNQ as dopant for various thicknesses of PTAA, according to an embodiment of the present invention;

FIG. 7D is a plot of the current density versus voltage (J-V) of semitransparent devices using TPFB as dopant for various thicknesses of PTAA, according to another embodiment of the present invention;

FIG. 7E is a plot of the current density versus voltage (J-V) in the forward scan (−0.1 V to 1.2 V) and reverse scan (1.2 V to −0.1 V) of the perovskite solar cell using 10 wt % TPFB-doped PTAA with illumination through MgF₂ side, according to an embodiment of the present invention;

FIG. 7F is a plot of the external quantum efficiency (EQE) spectrum of the perovskite solar cell using 10 wt % TPFB doped PTAA, according to an embodiment of the present invention;

FIG. 7G shows a photoluminescence plot of intensity versus wavelength of the perovskite layer on top of glass and PTAA doped with 1 wt % F4-TCNQ or 10 wt % TPFB, according to an embodiment of the present invention;

FIG. 7H is a plot of time-resolved photo-luminescence intensity versus time of the perovskite layer in contact with glass (upper curve) and PTAA doped with 1 wt % F4-TCNQ or 10 wt % TPFB (lower curves), according to an embodiment of the present invention;

FIG. 8A shows a three-dimensional schematic representation of the tandem CIGS-Perovskite tandem device (left) and a cross-section SEM image of the monolithic perovskite-CIGS tandem device (right), according to an embodiment of the present invention;

FIG. 8B is a plot of current density versus voltage (J-V) for the perovskite-CIGS tandem device/cell and efficiency at the maximum power point (inset), according to an embodiment of the present invention;

FIG. 8C is a plot of the EQE spectra for the subcells of the monolithic perovskite-CIGS tandem device/cell, according to an embodiment of the present invention; and

FIG. 8D is a plot of normalized PCE versus time of the tandem CIGS-Perovskite device, according to an embodiment of the present invention.

### DETAILED DESCRIPTION

Some embodiments of the current invention are discussed in detail below. In describing embodiments, specific terminology is employed for the sake of clarity. However, the invention is not intended to be limited to the specific terminology so selected. A person skilled in the relevant art will recognize that other equivalent components can be employed and other methods developed without departing from the broad concepts of the current invention. All references cited anywhere in this specification, including the Background and Detailed Description sections, are incorporated by reference as if each had been individually incorporated.

The combination of Cu(In,Ga)Se₂ (CIGS) with perovskite (PVSK) to provide PVSK/CIGS tandem solar cells offers a promising solution for both high performance and low-cost. Both perovskite and CIGS are compelling in their cost-effectiveness and high performance, making them highly attractive candidates for double junction tandem solar cells.

Different from the III-V tandem solar cells, the PVSK/CIGS tandem solar cells do not need high vacuum facilities, such as molecular beam epitaxy (MBE), metal-organic chemical vapor deposition (MOCVD), etc. Therefore, this could reduce the fabrication cost for such solar cells.

Compared to Silicon/PVSK tandem solar cells which require high quality silicon rear cells, PVSK/CIGS solar cells only need the commercialized CIGS rear cell to achieve high efficiency. In addition, as this is a thin film tandem solar cell, flexible tandem solar cells could be fabricated by this method.

For PVSK/CIGS tandem solar cells, we first report using a chemical-mechanical polishing (CMP) method to polish the interconnection layer and this key technique makes the devices more reliable and less expensive. In addition, we use an optically transparent electrode to help light harvesting, which is different from other tandem solar cells which use opaque electrodes. Therefore, our device efficiency is 80% higher than the prior results. For example, the conventionally reported highest efficiency of a PVSK/CIGS tandem solar cell is only 10.9%, which is published in “Teodor Todorov et al., Adv. Energy Mater. 2015, 5, 1500799.” The term “optically transparent” or “optically semi-transparent” is used herein throughout to mean having a transmission of radiation or light in the visible wavelength range, the ultraviolet wavelength range, and/or infrared wavelength range of at least 50%, for example, between 70% and 100%.

The conventional Todorov's PVSK/CIGS have an inferior efficiency. This can be attributed to various reasons. The present inventors have determined that the limited efficiency in the conventional PVSK/CIGS can be due to 1) the optical losses caused by the top opaque metal electrodes; 2) the intrinsic ZnO (i-ZnO) and aluminum doped ZnO (AZO) layers pertaining to typical CIGS cells are removed as zinc oxides can cause deterioration of the perovskite layer and this compromises the CIGS device architecture; the elimination of ZnO layer inevitably sacrifices the CIGS device performance; 3) the fill factor (F.F.) is reduced to 60% due to a high series or shunt resistance (Rs) caused by poor contact between the two subcells (CIGS and PVSK). Furthermore, as will be explained in the following paragraphs, the smoothness of the inter-connecting layer (ICL) can play a role in creating a reliable contact between the two sub-cells, since the planar perovskite solar cell is composed of several functional layers with thicknesses from few tens to hundreds of nanometers, which are sensitive to substrate roughness.

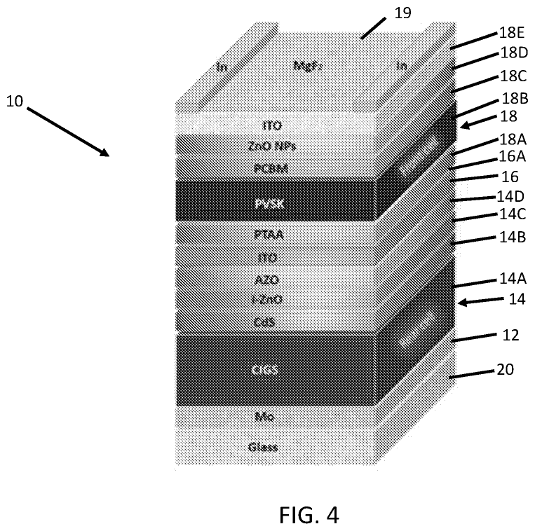

Accordingly, some embodiments of the present invention relate to Perovskite/Cu(In, Ga)Se₂ (PVSK/CIGS) tandem photovoltaic devices 10 and their fabrication techniques. FIG. 4, is a schematic illustration of a tandem photovoltaic device 10 according to an embodiment of the current invention. The tandem photovoltaic device 10 includes a first electrode 12, a CIGS light absorption section 14 on the first electrode 12, an interconnecting layer (ICL) 16 on the CIGS light absorption section 14, and a perovskite (PVSK) light absorption section 18 on the interconnecting layer 16. The interconnecting layer 16 has a polished surface 16A on which the perovskite light absorption section 18 is formed and the interconnecting layer 16 provides an electrically conducting and optically transparent connection between the CIGS light absorption section 14 and the perovskite light absorption section 18.

In some embodiments, the polished surface 16A of the interconnecting layer 16 has a maximum vertical distance (VD) less than 250 nm. In some embodiments, the polished surface 16A of the interconnecting layer (ICL) 16 has a maximum vertical distance (VD) less than 100 nm. In some embodiments, the polished surface 16A of the interconnecting layer 16 has a maximum vertical distance (VD) in the range of 100 nm to 5 nm. In some embodiments, the polished surface 16A of the interconnecting layer 16 has a maximum vertical distance (VD) in the range of 40 nm to 10 nm.

In some embodiments, the interconnecting layer (ICL) 16 is an ITO layer between 200 nm and 400 nm thick. In some embodiments, the interconnecting layer 16 is an ITO layer about 300 nm thick. In an embodiment, good performance was achieved with a 300 nm ITO layer. If the thickness is thinner than 200 nm, the polishing process could damage the CIGS solar cell, and if the thickness is higher than 400 nm, the optical loss will be more severe.

In some embodiments, the perovskite light absorption section 18 includes a hole transport layer (HTL) 18A formed on the interconnecting layer 16, the hole transport layer 18A including PTAA doped with at least one of F4-TCNQ and TPFB. (TPFB is 4-Isopropyl-4′-methyldiphenyliodonium Tetrakis(pentafluorophenyl)borate.) In some embodiments, the hole transport layer 18A includes PTAA doped with between 0.5 wt % to 2 wt % of F4-TCNQ and with between 5 wt % to 15 wt % of TPFB. In some embodiments, the hole transport layer 18A includes PTAA doped with about 1 wt % of F4-TCNQ and with about 10 wt % of TPFB.

In some embodiments, the first electrode 12 is formed on a substrate 20. In some embodiments, the substrate 20 is a flexible substrate. In some embodiments, the substrate 20 is a soda-lime glass substrate. In some embodiments, the first electrode 12 is Mo.

In some embodiments, the CIGS light absorption section 14 includes a CIGS absorber layer 14A and a CdS layer 14B deposited on the CIGS absorber layer 14A. In some embodiments, the CIGS light absorption section further includes an i-ZnO layer 14C formed on the CdS layer 14B and a BZO layer 14D formed on the i-ZnO layer 14C. In some embodiments, the perovskite light absorption section 18 includes a PCBM layer 18C formed on a perovskite absorber layer 18B, a layer of ZnO nanoparticles 18D formed on the PCBM layer 18C, and an ITO layer 18E formed on the layer of ZnO nanoparticles 18D, the ITO layer 18E being the second electrode. In some embodiments, the monolithic tandem photovoltaic device/cell 10 further includes an anti-reflection coating 19 formed on the second electrode 18E. In some embodiments, the anti-reflection coating 19 is a MgF₂ anti-reflection coating.

In some embodiments, the interconnecting layer (ICL) 16 is substantially optically transparent to light within an absorption band of the CIGS light absorption section 14.

In an embodiment, the total light current is attenuated about 7.5% after adding ITO layer 16 on the CIGS solar cell 14 within the spectrum from 300 to 1250 nm. The additional ITO layer light absorption could be reduced by adding some further optical design. As the desire for voltage improvement is much higher than current loss, the final efficiency is enhanced.

A method of producing a monolithic tandem photovoltaic cell according to some embodiments of the current invention includes providing a first electrode 12 on a substrate 20, producing a CIGS light absorption section 14 on the first electrode 12, depositing an interconnecting layer (ICL) 16 on the CIGS light absorption section 14, polishing the interconnecting layer 16, and producing a perovskite light absorption section 18 on the interconnecting layer 16. The interconnecting layer 16 provides an electrically conducting and optically transparent connection between the CIGS light absorption section 14 and the perovskite light absorption section 18.

In some embodiments, the polishing of the interconnecting layer 16 provides a surface 16A of the interconnecting layer 16 that has a maximum vertical distance (VD) less than 250 nm. In some embodiments, the polishing of the interconnecting layer 16 provides a surface 16A of the interconnecting layer 16 that has a maximum VD less than 100 nm. In some embodiments, the polishing of the interconnecting layer 16 provides a surface 16A of the interconnecting layer 16 that has a maximum VD in the range of 100 nm to 5 nm. In some embodiments, the polishing of the interconnecting layer 16 provides a surface 16A of the interconnecting layer 16 that has a maximum VD in the range of 40 nm to 10 nm.

In some embodiments, the depositing of the interconnecting layer 16 deposits an ITO layer about 300 nm thick. In some embodiments, the depositing of the interconnecting layer 16 deposits an Indium Tin Oxide (ITO) layer of between 200 nm to 400 nm thick.

In some embodiments, the producing of the perovskite light absorption section 18 on the interconnecting layer 16 includes depositing a hole transport layer (HTL) 18A on the interconnecting layer 16 and doping the hole transport layer 18A to increase hole conduction thereof.

According to other embodiments of the invention, a tandem device 10 having a transport top electrode 18E, suitable interconnecting layer (ICL) 16 and hole transporting layer (HTL) 18A, and successfully present a high-performance monolithic perovskite/CIGS tandem solar cell without modification of the CIGS device structure 14, i.e., by preserving its transparent conductive oxide (TCO) layers (i-ZnO) 14C and Boron-doped ZnO (BZO) layers 14D is constructed. For the two subcells, we apply a semitransparent perovskite section 18 with a band gap of 1.59 eV as a front cell, and CIGS section 14 with a bandgap of 1.00 eV as a rear cell. The certified tandem device power conversion efficiency (PCE) achieves 22.43% that is the highest PCE for thin film tandem solar cells and has doubled the previous record for the perovskite/CIGS monolithic tandem device structure 10.

A tandem solar cell with minimized thermalization losses has been proven a successful approach to overcome the Shockley-Queisser limit of a single junction cell. The tandem solar cell can realize the superposition of the open circuit voltage (V_{OC}) of both sub-cells and simultaneously preserve the high short circuit current density (J_{SC}) by utilizing photoactive materials with complementary absorption characteristics to harvest broader spectrum of sunlight.

The latest promising organic-inorganic hybrid PVSK and the CIGS thin film photovoltaic technology have emerged as an absorber material. Because both of PVSK and CIGS are solar materials having widely tunable band gaps from 1.0 to 1.7 eV for CIGS and 1.5 to 2.3 eV for PVSK, the combination of CIGS and PVSK indeed possesses great potential to realize a high efficiency tandem solar cell. These characteristics provide the potential to achieve the highest efficiency of double junction tandem solar cells, where the rear and front cells ought to have band gaps of 1.1 eV and 1.7 eV, respectively.

In some embodiments of the current invention, we demonstrate a high performance monolithic PVSK/CIGS tandem solar cell which also maintains the CIGS device structure.

Firstly, a rear CIGS solar cell is fabricated. The submicron-thick CIGS absorbers are deposited on Mo-coated soda-lime glass substrates with 2 μm thickness. After the deposition of CIGS absorber, a 50 nm CdS layer was deposited by chemical bath deposition. A 50 nm thick i-ZnO was subsequently deposited by RF-sputtering followed by sputtering deposition of a 300 nm thick AZO layer.

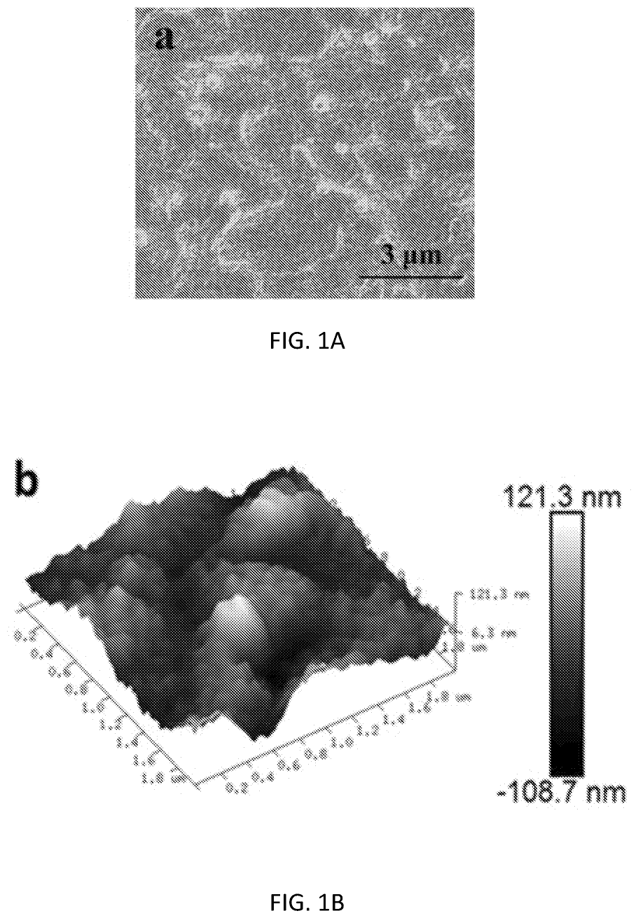

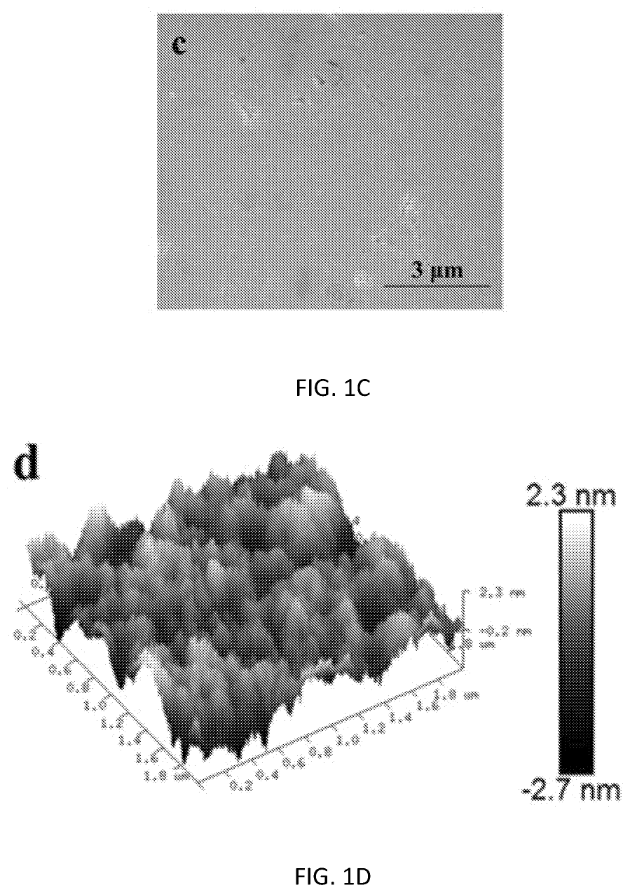

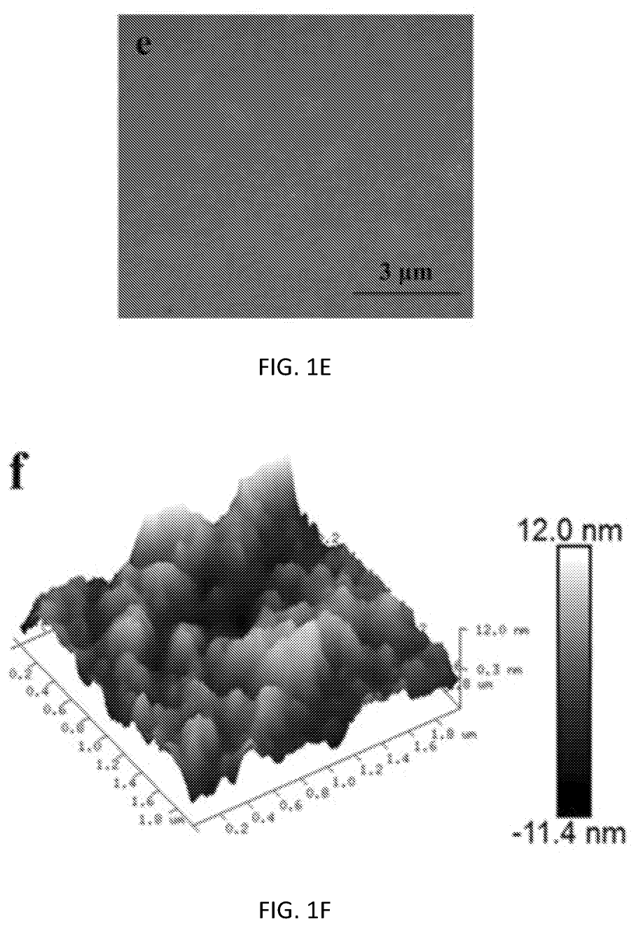

Secondly, the interconnection layer (ICL) of the tandem solar cell is deposited on CIGS layer. Indium tin oxide (ITO) and AZO transparent layers could be used as the interconnection layer. Usually, a considerable average roughness of AZO at the top of the CIGS device is about 300 nm, as shown in FIGS. 1A and 1B. FIG. 1A is a scanning electron microscope (SEM) image of the CIGS surface before chemical mechanical polishing (CMP), according to an embodiment of the present invention. FIG. 1B is an atomic force microscope (AFM) image of the CIGS surface before CMP, according to an embodiment of the present invention. As the thickness of the PVSK layer is around 350 nm, it is difficult to homogeneously stack the PVSK solar cell on top of the CIGS.

In order to flatten the CIGS device surface, we use chemical mechanical polishing (CMP) to realize planar transparent conducting oxide (TCO) layers. AZO and ITO layers were polished using SiO₂ and Al₂O₃ slurry, respectively. Colloid Al₂O₃ slurry with PH value 4 was used for ITO polishing and colloid SiO₂ slurry with PH value 8 was used for AZO polishing. The CIGS solar cell was polished with flatten rotation rate 40 rpm for 5 min. After polishing, we find that the roughness of the ITO and AZO layers were reduced to 5 nm and 20 nm, respectively. FIG. 1C is a SEM image of ITO/AZO bilayer surface after CMP polishing, according to an embodiment of the present invention. FIG. 1D is an AFM image of ITO/AZO bilayer surface after CMP polishing, according to an embodiment of the present invention. FIG. 1E is a SEM image of AZO surface after CMP polishing, according to an embodiment of the present invention. FIG. 1F is an AFM image of AZO surface after CMP polishing, according to an embodiment of the present invention.

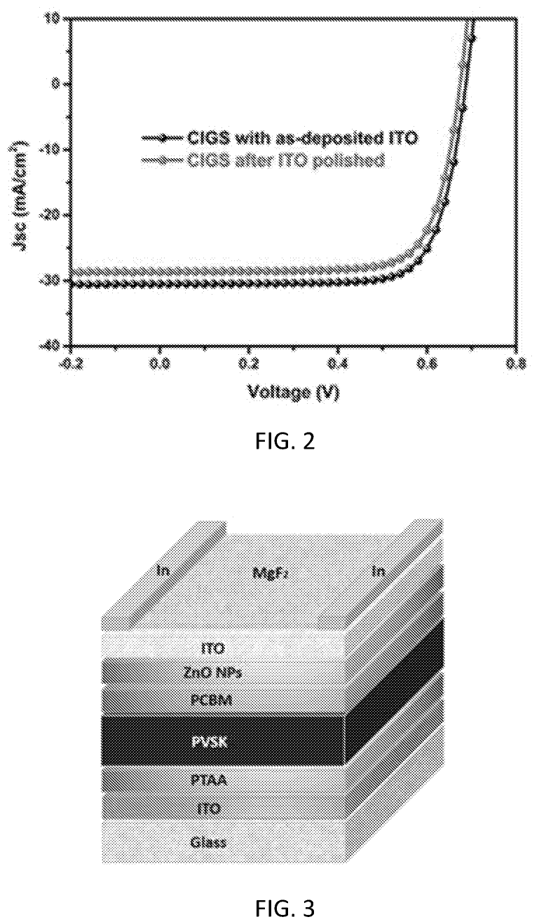

FIG. 2 is a plot of current density per surface area J_{SC} (in mA/cm²) versus voltage showing the curves of CIGS solar cells with as-deposited ITO and after ITO polishing, according to an embodiment of the present invention. The current and voltage is measured under measured under AM1.5G illumination, This shows that CMP can effectively planarize the surfaces of CIGS solar cells without trading off device efficiency.

Thirdly, a front semitransparent PVSK solar cell is fabricated. FIG. 3 is a schematic three-dimensional representation of the semi-transparent single-junction perovskite (PVSK) solar cell, according to an embodiment of the present invention. The semi-transparent PVSK solar cell has an inverted P-I-N structure, as shown in FIG. 3. An ITO layer is used as the top electrode in this structure to allow for sufficient light transmission.

FIG. 4 is a schematic three-dimensional representation of the semi-transparent PVSK/CIGS tandem solar cell, according to an embodiment of the present invention. Various band gaps of PVSKs are attempted in order to achieve current matching between the PVSK and CIGS in the monolithic cell. In an embodiment, a composition of (FAPbI₃)_{0.85}(MAPbBr₃)_{0.15} for the PVSK is used as it provided optimal performance. However, other compositions can also be used. PTAA (Sigma) is used as a hole transporting layer (HTL) for PVSK solar cells. PTAA film is prepared by spin coating 1 wt % PTAA solution doped with 1 wt % 2,3,5,6-Tetrafluoro-7,7,8,8-tetracyanoquinodimethane (F4-TCNQ) (Sigma) at 3,000 rpm, and the as-prepared film thermally annealed at 110° C. for 10 min. The perovskite layer is deposited by the solvent-engineering technique using a mixing solvent (in which the volume ratio of dimethyl sulfoxide (DMSO) (Sigma) to N, N-dimethylformamide (DMF) (Sigma) was 15:85). Then 1.14 mmol of FAPbI₃ and 0.20 of mmol MAPbBr₃ (i.e., 196 mg of FAI (Dyesol), 23 mg of MABr (Dyesol), 529 mg of PbI₂ (obtain from Alfa Aesar) and 74 mg of PbBr₂ (obtained from Alfa Aesar) are dissolved in the mixing solvent (1 ml) as a (FAPbI₃)_{0.85}(MAPbBr₃)_{0.15} precursor solution. The PVSK solution is then coated onto the HTL/ITO substrate 4,000 rpm for 80 s. The wet spinning film is quenched by dropping 100 μl of anhydrous chlorobenzene (CB) (obtained from Sigma) onto it. After spin coating, the film is annealed at 110° C. for 20 min. A 2 wt. % solution of PCBM (obtained from Solarmer) in anhydrous CB is spun at 2,000 rpm for 45 s. ZnO (obtained from Sigma) nanoparticle inks with 15 nm average particle diameter dispersed in IPA (2.5 wt. %) are spun on at 5,000 rpm. Two layers of nanoparticles are spun sequentially to produce an approximately 50 nm thick layer. The ZnO films are dried at 90° C. for 45 s. For the semi-transparent devices, 100 nm ITO layer is deposited as a top electrode material by using ULVAC RF sputtering system. Then, 150 nm of MgF₂ (obtained from Alfa Aesar) is thermally evaporated as an anti-reflection coating.

The average transmittance of semi-transparent perovskite cell in the wavelength region between 770 nm and 1100 nm is over 85%, and gradually decreases from 770 to 525 nm. Below 525 nm, the light is entirely absorbed by the perovskite cell, which indicates that the perovskite cell with composition of (FAPbI₃)_{0.85}(MAPbBr₃)_{0.15} is an ideal candidate to couple with CIGS for near-infrared harvesting.

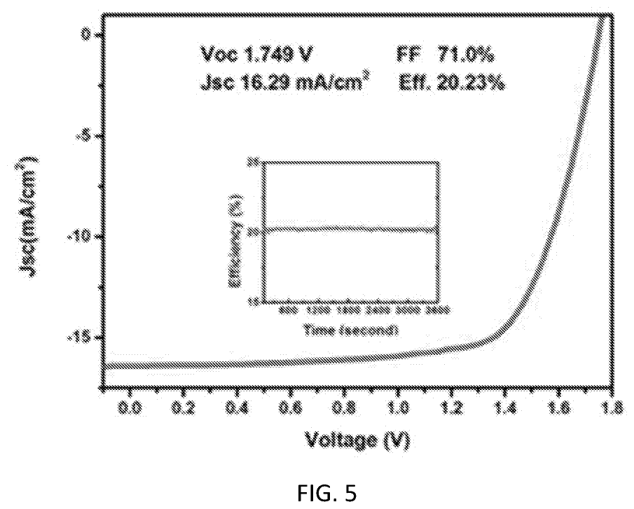

FIG. 5 shows is a plot of the current density J_{SC} (in mA/cm2) versus the voltage applied showing the current density-voltage curve (NREL-certified) and the efficiency at the maximum power point (inset) of the PVSK/CIGS tandem device, according to an embodiment of the present invention.

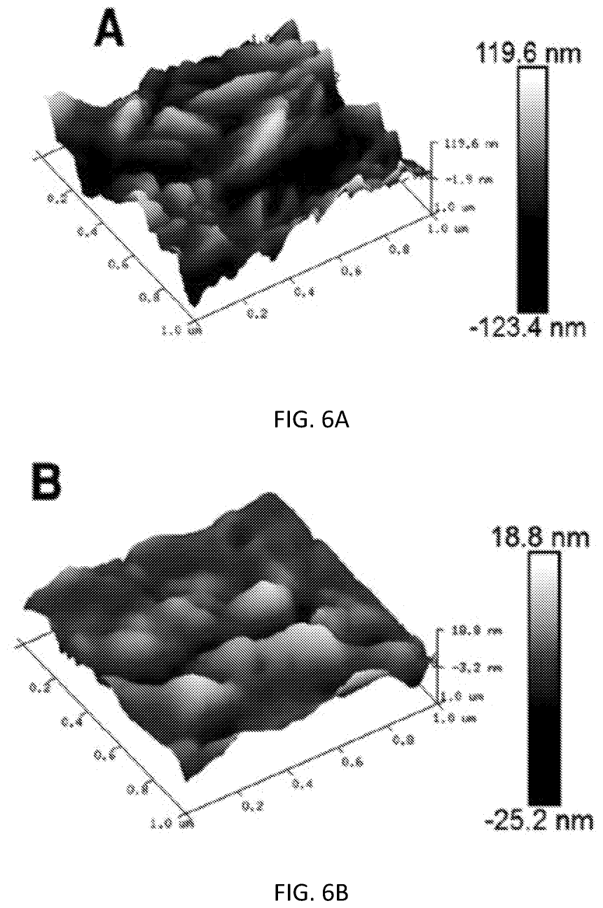

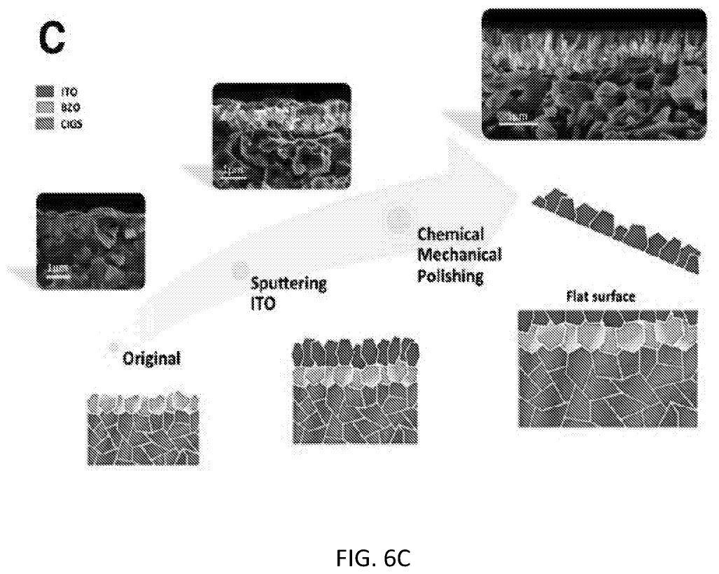

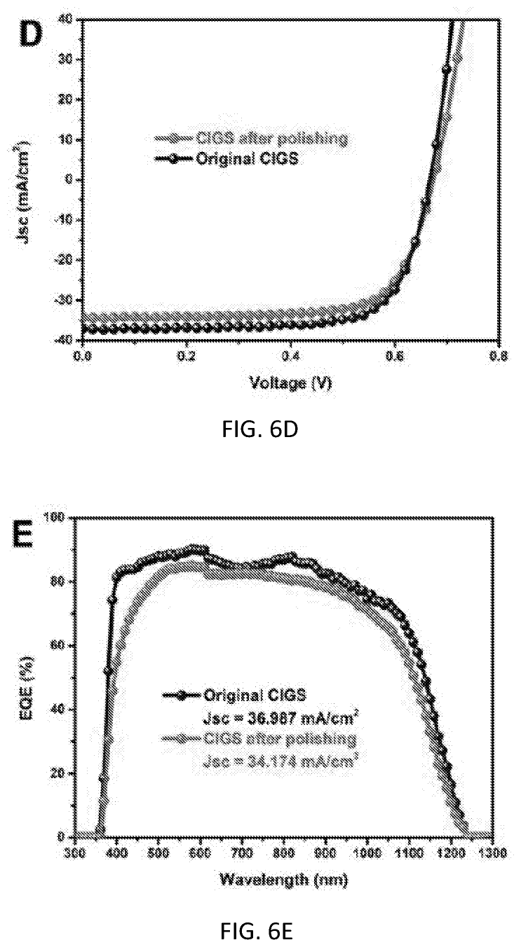

In order to design a functional ICL, the CIGS device surface has to be taken carefully into consideration. FIG. 6A is an atomic force microscope image of CIGS surface prior to CMP polishing, according to an embodiment of the invention. In an embodiment, BZO is the top layer of the CIGS device, which has a surface roughness of about 60 nm and the maximum vertical distance (VD) of natural BZO layer texture can reach more than 250 nm (as shown in FIG. 6A). For such considerable roughness and VD, we suspect that they originate from the difference between peaks and valleys of the CIGS absorber layer. In addition, inhomogeneous nucleation of the bottom CdS buffer layer can also enhance BZO roughness.

The maximum length of VD is comparable to the perovskite absorber layer that is usually around 300 to 600 nm, and even larger than the thickness of the perovskite charge transporting layers. With these perceivable VDs, it becomes challenging to stack the perovskite solar cell on top of the CIGS with a homogeneous layer-by-layer structure. The rough BZO surface can cause perovskite subcell failure as the BZO peaks/rods can easily entangle the functional layers in perovskite device to induce electrical shorting pathways between the top contact of perovskite subcell and the BZO layer. Being aware of this fact, we confirm that the nature of CIGS device surface can be problematic for building a smooth ICL on top of it, and hence the ICL roughness is pivotal in realizing high-performance perovskite/CIGS tandem solar cells. To address this issue, we provide a smooth ICL while retaining original CIGS device structure. First, we deposit an ITO layer, followed by chemical mechanical polishing (CMP) to smooth out the ITO surface. By adding a sufficiently thick ITO layer, it can serve as a buffer layer for the CMP process to level out the relatively large VD of the BZO layer. In an embodiment, the ITO layer is polished using commercialized SiO₂ slurry. After polishing, the maximum VD of the ITO layers is reduced to 40 nm (FIG. 6B). FIG. 6B is an atomic force microscope image of the CIGS surface after CMP polishing, according to an embodiment of the present invention. This reduction of the maximum VD of the ITO layer to 40 nm is relatively a large reduction compared to the original BZO surface, and renders the ITO surface smooth enough for subsequent fabrication of the functional perovskite front cell. Notably, the CMP process does not polish the BZO layer such that we can retain the original CIGS solar cell structure as shown in FIG. 6C. FIG. 6C shows a process diagram of various steps of fabrication of the device and cross-section SEM images of the CMP processing on the CIGS surface, according to an embodiment of the present invention. Furthermore, the BZO work function (−4.0 eV) is lower than Poly[bis(4-phenyl)(2,4,6-trimethylphenyl)amine] (PTAA) (−5.1 eV, the HTL of perovskite subcell), which causes a large contact potential barrier. This ITO layer can efficiently modify the surface work function to create a better Ohmic contact for hole transportation. Based on our experiments, a 300 nm ITO layer is sufficient to carry out the CMP process and fully cap the BZO peaks and rods.

FIG. 6D is a graph of the current-density versus voltage of the original CIGS solar cells and after CMP polishing with a step size of 0.02 V and a scan velocity of 0.1 V/s, measured under AM1.5G illumination, according to an embodiment of the present invention. The current density-voltage (J-V) curves of the stand-alone original and polished CIGS solar cells are compared in FIG. 6D and the data is shown in TABLE 1 below.

TABLE 1
Performances of CIGS solar cells before and after CMP polishing.

| | V_{OC} | J_{SC} | F.F. | PCE |
|---|---|---|---|---|
| | (V) | (mA/cm²) | (%) | (%) |
| Original CIGS | 0.676 | 37.10 | 74.74 | 18.74 |
| CIGS solar cell after | 0.674 | 34.34 | 72.36 | 16.75 |
| ITO polishing | | | | |

As shown in TABLE 1, it is found that the V_{OC} is substantially constant, which further implies that CMP processing does not damage the CIGS device structure. The current density J_{SC} decreases slightly from 37.10 to 34.34 mA/cm² for the ITO-polished device. The current density J_{SC} drop can be due to the additional light absorption by the ITO layer, as we observe with the smaller external quantum efficiency (EQE) intensity across the entire response region, as shown in FIG. 6E. FIG. 6E is a plot of external quantum efficiency (EQE) versus wavelength of radiation or illumination incident on the device showing a difference between the original CIGS and the CIGS after polishing, according to an embodiment of the present invention. Particularly, the EQE of the ITO-polished device is clearly lower than the original CIGS device at the wavelength from 400 nm to 500 nm. This response region is corresponding to the smaller bandgap of ITO compared to BZO, and therefore provides evidence that the ITO layer would absorb a portion of the incident light. However, it is noted that the influence of ITO absorption at shorter wavelengths is negligible as the CIGS subcell is designated as a rear cell in the tandem device structure.

After polishing, the fill factor (F.F.) reduced from 74.74% to 72.36%. The F.F. reduction is mainly induced by the shunt resistance (Rs) increase rather than the shunt resistance decrease, as shown in FIG. 6D. The Rs increase could be attributed to the bad ITO lateral conductivity. However, because the ITO layer is used as the ICL for the tandem solar cell, the lateral conductivity does not affect the charge carrier transportation between the front and rear subcells. Therefore, the F.F. decrease of the CIGS rear cell would not have a negative impact on the tandem device performance.

After polishing the ITO layer of the CIGS device, the PCE decreased slightly from 18.74% to 16.75%. If we exclude the F.F. deficit influence, there will be only a 1.386 mA/cm² current loss in the wavelength region from 750 to 1250 nm. This result shows that the CMP process can effectively flatten the ICL without sacrificing the efficiency of the CIGS subcell. This flattening/polishing step can result in the production of high performance perovskite/CIGS tandem solar cells for two reasons: i) the CIGS solar cell structure is not modified in that its high efficiency is preserved, and ii) CMP is a common processing technique in the semiconductor industry that is reliable and compatible with conventional semiconductor manufacturing, which will facilitate wide spread commercialization.

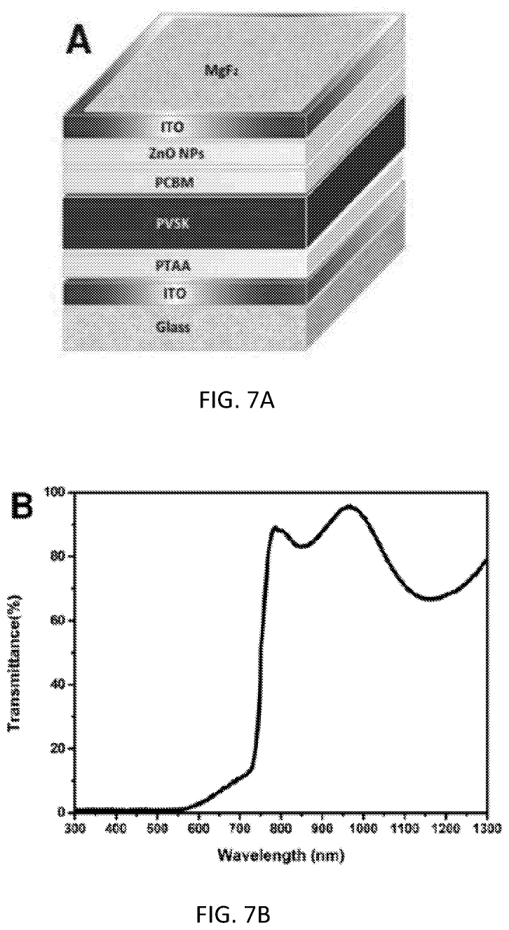

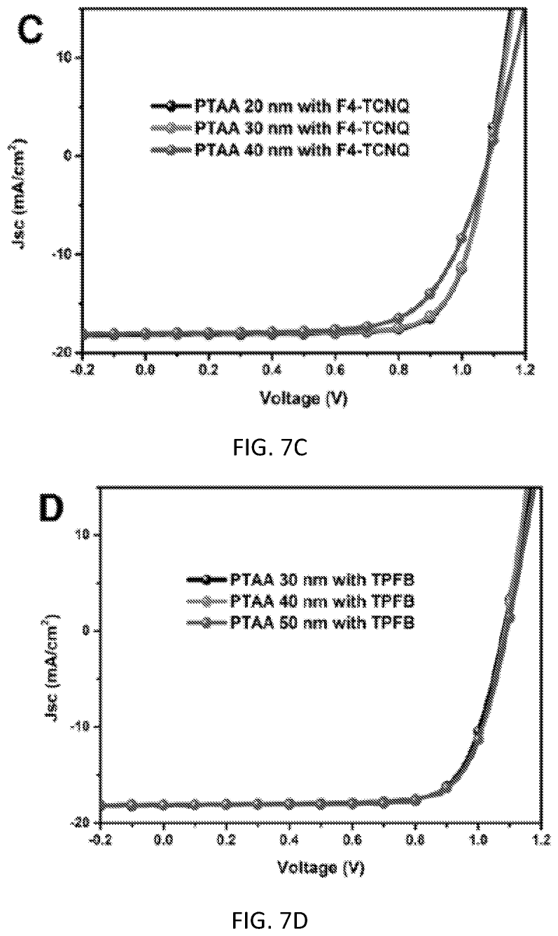

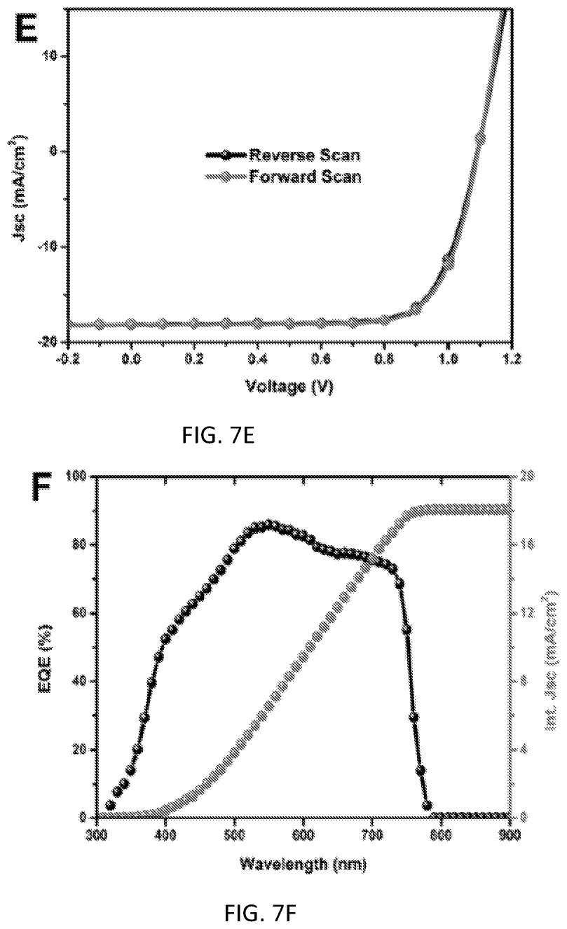

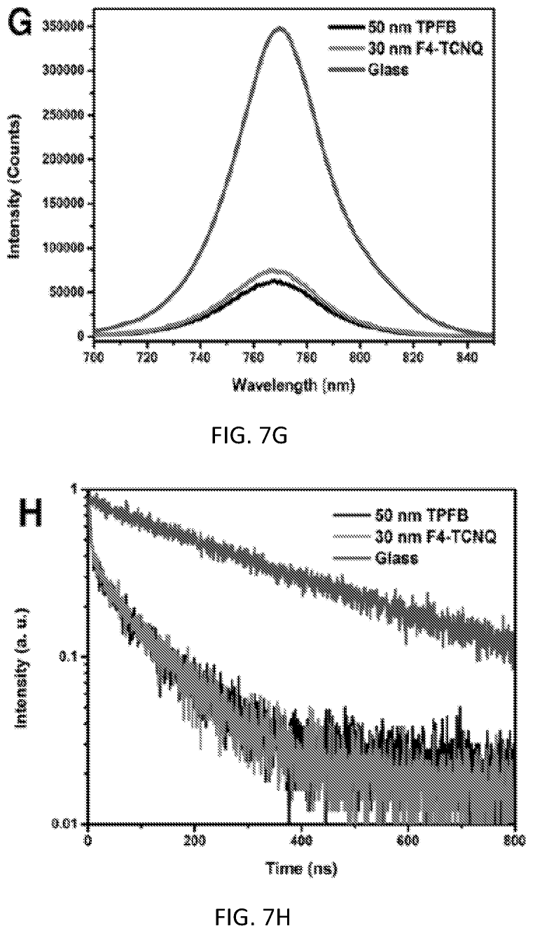

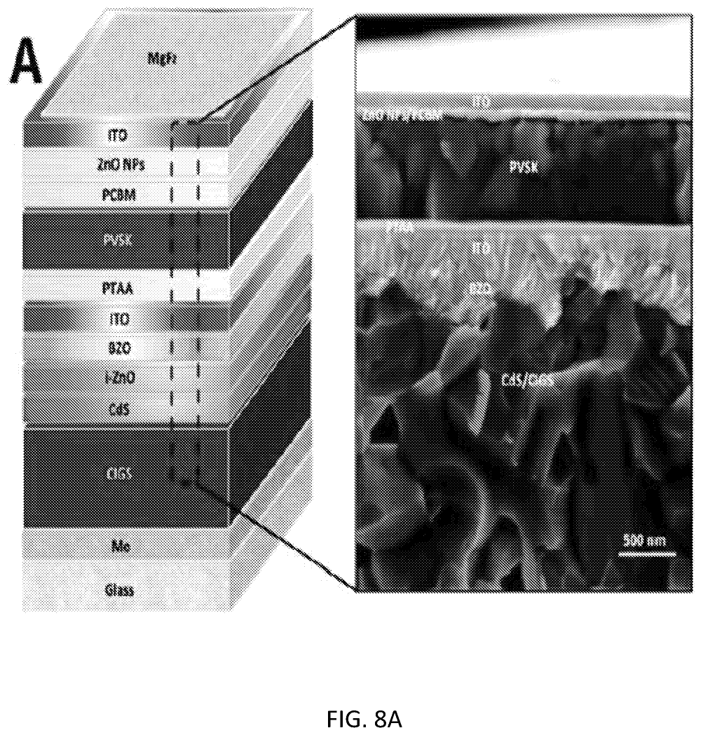

FIG. 7A is a three-dimensional schematic representation of a semitransparent perovskite solar cell with inverted structure (i.e., p-i-n), according to an embodiment of the present invention. The architecture of this semitransparent cell corresponds to the architecture used in the present tandem solar cell. Instead of using a metal electrode, a 100 nm ITO layer is used as the top contact in this structure to allow for sufficient light transmission. ITO is substantially transparent in a broad spectrum of wavelengths. Various band gaps of perovskites are attempted in order to achieve current matching between the two subcells in the monolithic cell. In an embodiment, the following composition for the perovskite is selected: Cs_{0.09}FA_{0.77}MA_{0.14}Pb(I_{0.86}Br_{0.14})₃. This composition provides the best performance according to the results of our testing. The band gap of this composition is identified to be 1.59 eV through UV-Vis measurements. In an embodiment, according to optical simulation results, a 600 nm perovskite layer, for example, may provide adequate current density to match the CIGS rear cell current density. However, other layers of perovskite with other thicknesses can also provide desired current densities to match the CIGS current density depending on the CIGS configuration used.

FIG. 7B shows the optical transmittance of the semitransparent perovskite single junction cell, according to an embodiment of the present invention. The average transmittance of semi-transparent perovskite cell in the wavelength region between 770 nm and 1300 nm is over 80%. This allows most of the longer wavelength light to be absorbed by the CIGS rear cell. The transmittance gradually decreases for wavelengths between 770 nm and 550 nm as light is gradually absorbed by the perovskite cell. The light is substantially fully absorbed by the perovskite cell for wavelengths below 550 nm. As a result, the perovskite cell with the composition of Cs_{0.09}FA_{0.77}MA_{0.14}Pb(I_{0.86}Br_{0.14})₃ can be a good candidate to couple with CIGS for near-infrared harvesting, for example.

While connecting a semitransparent perovskite subcell with a CIGS subcell via ICL, the thickness and coverage of the first layer on top of the ICL can play an important role for tandem device performance. This may be due to the planar perovskite device structure that has limited tolerance to the substrate roughness. As discussed in the above paragraphs, the polished ICL can still preserve about 40 nm for its VD, which may be considerable for the HTL of perovskite subcell. Given this concern, we conducted experiments to study the solar cell performance versus the HTL thickness. In this study, PTAA is selected as the HTL layer, and two different following molecules A) and B) are used as dopants to enhance the HTL conductivity.

A) 2,3,5,6-Tetrafluoro-7,7,8,8-tetracyanoquinodimethane (F4-TCNQ); and

B) 4-Isopropyl-4′-methyldiphenyliodoniumTetrakis(pentafluorophenyl)borate (TPFB)

It is worth noting that, in an embodiment, PTAA is deposited using a low-temperature annealing process (110° C.) which can successfully avoid damage to the rear CIGS solar cell since the PN junction in the CIGS solar cell cannot tolerate temperatures higher than 150° C.

FIG. 7C is a plot of the current density versus voltage (J-V) of semitransparent devices using F4-TCNQ as dopant for various thicknesses of PTAA, according to an embodiment of the present invention. FIG. 7D is a plot of the current density versus voltage (J-V) of semitransparent devices using TPFB as dopant for various thicknesses of PTAA, according to another embodiment of the present invention. In these embodiments, the illumination is applied, for example, through the MgF₂ side. TABLE 2 summarizes corresponding device parameters.

TABLE 2

| | | V_{OC} | J_{SC} | F.F. | PCE |
|---|---|---|---|---|---|
| | | (V) | (mA/cm²) | (%) | (%) |
| Perovskite solar | 20 nm | 1.084 | 18.10 | 75.60 | 14.83 |
| cell using | 30 nm | 1.086 | 18.12 | 74.46 | 14.65 |
| F4-TCNQ doped | 40 nm | 1.086 | 18.01 | 67.59 | 13.22 |
| PTAA as HTL | 30 nm | 1.083 | 18.14 | 74.03 | 14.54 |
| Perovskite solar | 40 nm | 1.084 | 18.13 | 74.89 | 14.72 |
| cell using | 50 nm | 1.091 | 18.15 | 75.49 | 14.95 |
| TPFB doped | 50 nm | 1.092 | 18.14 | 75.28 | 14.91 |
| PTAA as HTL | forward scan | | | | |

With the same concentration of F4-TCNQ, the device performance with the application of 30 nm PTAA is similar to the device performance with the application of 20 nm PTAA. However, the shunt resistance Rs increased when the PTAA reached 40 nm, which leads to a device F.F. and efficiency reduction. In the above examples, the best device performance is achieved when using 20 nm F4-TCNQ-doped PTAA at a voltage V_{OC} of 1.084 V, a current density J_{SC} of 18.10 mA/cm² and F. F. of 75.60%. This results in a device having an overall device efficiency of 14.83%. In an embodiment, the desired F4-TCNQ/PTAA ratio is 1 wt %. Increasing F4-TCNQ concentration does not appear to help decrease the shunt resistance Rs as F4-TCNQ aggregates within the PTAA film. Therefore, in these examples, the most suitable thickness for F4-TCNQ-doped PTAA is less than 30 nm (for example, 20 nm).

On the other hand, the J-V curves of the perovskite device using TPFB-doped PTAA (TPFB/PTAA equal to 10 wt %) exhibited less sensitivity to the HTL thickness. The device performances are similar when using 30 to 50 nm PTAA. Surprisingly, the devices applying thicker TPFB-doped PTAA present superior performance than the devices with thinner F4-TCNQ-doped PTAA. In an embodiment, the best device is obtained by using 50 nm PTAA, with a voltage V_{OC} of 1.091 V, current density J_{SC} of 18.15 mA/cm², F.F. of 75.49%, and PCE of 14.95%. The higher F.F. in the device in this example can be explained by the shunt resistance Rs reduction from the HTL, wherein the TPFB-doped PTAA has a higher conductivity than F4-TCNQ-doped PTAA. Considering the maximum vertical distance VD of the polished CIGS surface is about 40 nm in this example, thick PTAA is expected to provide a better coverage on the surface. Therefore, we adopted the TPFB-doped PTAA as the HTL for the perovskite front cell in the tandem architecture.

FIG. 7E is a plot of the current density versus voltage (J-V) in the forward (−0.1 V to 1.2 V) and reverse (1.2 V to −0.1 V) scan of the perovskite solar cell using 10 wt % TPFB-doped PTAA with illumination through the MgF₂ side, according to an embodiment of the present invention. The semitransparent perovskite device using TPFB-doped PTAA is scanned from positive to negative (reverse scan) and negative to positive (forward scan) voltages with a step size of 20 mV and a delay time of 0.2 s for each data point in the J-V measurement. The photocurrent hysteresis is negligible as the perovskite grain boundaries are well passivated by [6,6]-phenyl-C61-butyric acid methyl ester (PCBM).

FIG. 7F is a plot of the external quantum efficiency (EQE) spectrum of the perovskite solar cell using 10 wt % TPFB doped PTAA, according to an embodiment of the present invention. In this embodiment, the current density J_{SC} calculated from the EQE curve is 18.062 mA/cm². The EQE data for the semitransparent perovskite cell shows an offset position at 780 nm, which is consistent with the UV-Vis results. The integrated JSC from the EQE using the AM 1.5 reference spectra reaches 18.062 mA/cm².

In an embodiment, device performances may be closely correlated to charge carriers dynamics in perovskite solar cells. We analyzed the charge collection and transportation using steady-state photoluminescence (PL) and time-resolved PL (TRPL). FIG. 7G shows a photoluminescence plot of intensity versus wavelength of the perovskite layer on top of glass and PTAA doped with 1 wt % F4-TCNQ or 10 wt % TPFB, according to an embodiment of the present invention. FIG. 7G shows steady state PL spectroscopy of perovskite films on three different substrates (glass, ITO/F4-TCNQ-doped PTAA, and TPFB-doped PTAA). A clear quenching is observed on both types of PTAA compared to the perovskite layers on glass. This quenching is a powerful evidence of efficient charge transfer from the photoactive layer to the transport layer on contact with the two types of PTAA.

FIG. 7H is a plot of time-resolved photo-luminescence intensity versus time of the perovskite layer in contact with glass (upper curve) and PTAA doped with 1 wt % F4-TCNQ or 10 wt % TPFB (lower curves), according to an embodiment of the present invention. The time-resolved photo-luminescence (TRPL) responses show a decrease in the PL lifetime from 335 ns to 84 ns and 78 ns in the presence of 30 nm F4-TCNQ and 50 nm TPFB doped PTAA, respectively. This implies that charge carriers within the perovskite layer can be extracted effectively by these two types of PTAA. The above results indicate that TPFB is a well-suited dopant for a PTAA HTL in the CIGS/perovskite tandem architecture.

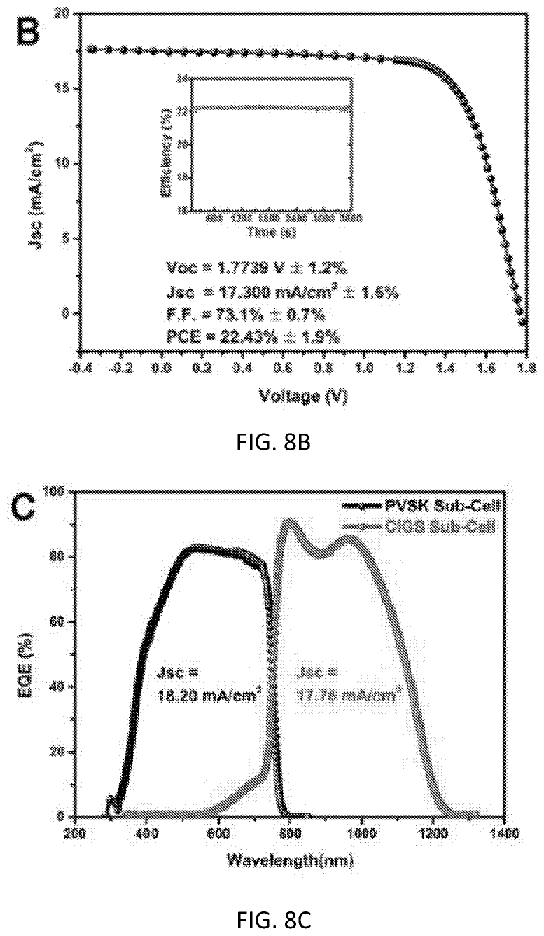

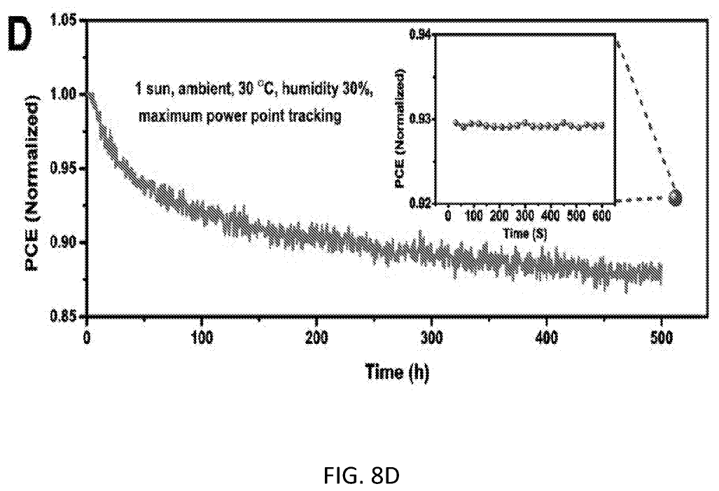

FIG. 8A shows a three-dimensional schematic representation of the tandem CIGS-Perovskite tandem device (left) and a cross-section SEM image of the monolithic perovskite-CIGS tandem device (right), according to an embodiment of the present invention. As shown in FIG. 8A, the polished ITO layer is used as the ICL to bridge two subcells together without the need for a tunneling junction.

FIG. 8B is a plot of current density versus voltage (J-V) for the perovskite-CIGS tandem device/cell and efficiency at the maximum power point (inset), according to an embodiment of the present invention. In an embodiment, the tandem device/cell has an area of 0.042 cm². The tandem cell exhibits a voltage V_{OC} of 1.774 V that equals to the sum of the standalone V_{OC} of subcells. The F.F. of the tandem cell reaches up to 73.1%, implying that ITO and PTAA provide a good series connection between subcells. The current density J_{SC} of the device is 17.3 mA/cm², resulting in an overall device PCE of 22.43%. We observe a negligible hysteresis that is consistent with the behaviors of the semitransparent perovskite solar cells (as discussed above).

FIG. 8C is a plot of the EQE spectra for the subcells of the monolithic perovskite-CIGS tandem device/cell, according to an embodiment of the present invention. The integrated current density J_{SC} from the EQE curves for the top and rear cells are 18.20 mA/cm² and 17.76 mA/cm², respectively, showing well-current-matched subcells. It is noted that the EQE of the ITO-polished CIGS is lower than 80% from 800 nm to 1100 nm, as shown in FIG. 6E. However, the EQE can be increased to around 85%, as shown in FIG. 8C, by applying a MgF₂ layer. This improvement can minimize the efficiency loss of the polished CIGS. Tandem devices with larger area (0.52 cm²) are also fabricated achieving a 20.8% PCE.

In addition to high PCE, the long-term stability is also another benchmark for industrialization of perovskite devices. Several aging methods can be used to estimate a stability of the device in which the ion migration effects are excluded. For example, we monitored the un-encapsulated tandem device performance by aging for 500 hours under continuous one-sun illumination and maximum power point tracking at 30° C. ambient environment. The device started with 22.0% PCE and retained above 88% of its initial efficiency with aging for over 500 hours. The device can recover 93% of its initial PCE after 12 hours being kept in dark without load. FIG. 8D is a plot of normalized PCE versus time of the tandem CIGS-Perovskite device, according to an embodiment of the present invention. The un-encapsulated device maintained 88% of its initial PCE after 500 hours aging under continuous one-sun illumination and maximum power point tracking at 30° C. ambient environment. The inset shows that the device can recover 93% of its initial performance after 12 hours resting period without load and illumination. The top transparent metal oxide layers (composed of ZnO nanoparticles and sputtered ITO) can effectively resist moisture ingress, so that this structure can help the perovskite compounds remain stable without severe degradation over time.

In the CIGS-Perovskite tandem device, a CdS layer is provided between the CIGS layer and the PVSK layer. The CdS buffer layer can be replaced by other comparable or equivalent buffer material, such as Zn(O, S, OH), as CdS is known to be a relatively toxic substance. In addition to solving the problem of toxicity, the working period of the perovskite/CIGS tandem solar cell can also be extended. In an embodiment, when the PVSK front cell has shown some environmental degradation, the degraded PVSK front cell can be removed and the CIGS cell reused. The CIGS solar cells can be reused after washing out the degraded perovskite front cell. Indeed, because the PTAA is applied as the HTL material, the whole perovskite front cell can be removed from the CIGS rear cell by dissolving in chlorobenzene and N, N-dimethylformamide. The CIGS rear cell keeps the same performance when the front perovskite cell is removed, demonstrating that the fabrication and dissolving processes of the front PVSK cell does not damage the CIGS cell. Therefore, by taking advantage of this feature, the CIGS cell can be either used as a single junction cell or reused as a rear cell in tandem PVSK-CIGS devices. Similar PCEs can be achieved with the reused CIGS-PVSK tandem devices as the PCEs of the original PVSK-CIGS tandem devices. This result demonstrates that the CIGS device can be recycled over many cycles to improve the working period of perovskite/CIGS tandem solar cells and thus reduce cadmium pollution.

More generally and as it can appreciated from the above paragraphs, a monolithic tandem photovoltaic cell according to some embodiments of the current invention include a first electrode, a CIGS light absorption section on the first electrode, an interconnecting layer on the CIGS light absorption section, and a perovskite light absorption section on the inter-connecting layer. The interconnecting layer has a polished surface on which the perovskite light absorption section is formed and the interconnecting layer provides an electrically conducting and optically transparent connection between the CIGS light absorption section and the perovskite light absorption section.

In some embodiments, the polished surface of the interconnecting layer has a maximum vertical distance (VD) less than 250 nm. In some embodiments, the polished surface of the interconnecting layer (ICL) has a maximum vertical distance (VD) less than 100 nm. In some embodiments, the polished surface of the interconnecting layer has a maximum vertical distance (VD) in the range of 100 nm to 5 nm. In some embodiments, the polished surface of the interconnecting layer has a maximum vertical distance (VD) in the range of 40 nm to 10 nm.

In some embodiments, the interconnecting layer is an ITO layer between 200 nm and 400 nm thick. In some embodiments, the interconnecting layer is an ITO layer about 300 nm thick. In an embodiment, good performance was achieved with a 300 nm ITO layer. If the thickness is thinner than 200 nm, the polishing process could damage the CIGS solar cell, and if the thickness is higher than 400 nm, the optical loss will be more severe.

In some embodiments, the perovskite light absorption section includes a hole transport layer formed on the interconnecting layer, the hole transport layer including PTAA doped with at least one of F4-TCNQ and TPFB. (TPFB is 4-Isopropyl-4′-methyldiphenyliodonium Tetrakis(pentafluorophenyl)borate.) In some embodiments, the hole transport layer includes PTAA doped with between 0.5 wt % to 2 wt % of F4-TCNQ and with between 5 wt % to 15 wt % of TPFB. In some embodiments, the hole transport layer includes PTAA doped with about 1 wt % of F4-TCNQ and with about 10 wt % of TPFB.

In some embodiments, the first electrode is formed on a substrate. In some embodiments, the substrate is a flexible substrate. In some embodiments, the substrate is a soda-lime glass substrate. In some embodiments, the first electrode is Mo.

In some embodiments, the CIGS light absorption section includes a CIGS absorber layer and a CdS layer deposited on the CIGS absorber layer. In some embodiments, the CIGS light absorption section includes an i-ZnO layer formed on the CdS layer and a BZO layer formed on the i-ZnO layer. In some embodiments, the perovskite light absorption section includes a PCBM layer formed on a perovskite absorber layer, a layer of ZnO nanoparticles formed on the PCBM layer, and an ITO layer formed on the layer of ZnO nanoparticles, the ITO layer being the second electrode. In some embodiments, the monolithic tandem photovoltaic cell further includes an anti-reflection coating formed on the second electrode. In some embodiments, the anti-reflection coating is a MgF₂ anti-reflection coating.

In some embodiments, the interconnecting layer is substantially optically transparent to light within an absorption band of the CIGS light absorption section.

In an embodiment, the total light current is attenuated about 7.5% after adding ITO layer on the CIGS solar cell within the spectrum from 300 to 1250 nm. The additional ITO layer light absorption could be reduced by adding some further optical design. As the desire for voltage improvement is much higher than current loss, the final efficiency is enhanced.

A method of producing a monolithic tandem photovoltaic cell according to some embodiments of the current invention includes providing a first electrode on a substrate, producing a CIGS light absorption section on the first electrode, depositing an interconnecting layer on the CIGS light absorption section, polishing the interconnecting layer, and producing a perovskite light absorption section on the inter-connecting layer. The interconnecting layer provides an electrically conducting and optically transparent connection between the CIGS light absorption section and the perovskite light absorption section.

In some embodiments, the polishing of the interconnecting layer provides a surface of the interconnecting layer that has a maximum vertical distance (VD) less than 250 nm. In some embodiments, the polishing of the interconnecting layer provides a surface of the interconnecting layer that has a maximum VD less than 100 nm. In some embodiments, the polishing of the interconnecting layer provides a surface of the interconnecting layer that has a maximum VD in the range of 100 nm to 5 nm. In some embodiments, the polishing of the interconnecting layer provides a surface of the interconnecting layer that has a maximum VD in the range of 40 nm to 10 nm.

In some embodiments, the depositing of the interconnecting layer deposits an ITO layer about 300 nm thick. In some embodiments, the depositing of the interconnecting layer deposits an Indium Tin Oxide (ITO) layer of between 200 nm to 400 nm thick.

In some embodiments, the producing of the perovskite light absorption section on the inter-connecting layer includes depositing a hole transport layer on the interconnecting layer and doping the hole transport layer to increase hole conduction thereof.

According to other embodiments of the invention, a tandem device having a transport top electrode, suitable inter-connecting layer (ICL) and hole transporting layer (HTL), and successfully present a high-performance monolithic perovskite/CIGS tandem solar cell without modification of the CIGS device structure, i.e., by preserving its transparent conductive oxide (TCO) layers (i-ZnO and Boron-doped ZnO (BZO) layers is constructed. For the two subcells, we apply a semitransparent perovskite with a band gap of 1.59 eV as a front cell, and CIGS with a bandgap of 1.00 eV as a rear cell. The certified tandem device power conversion efficiency (PCE) achieves 22.43% that is the highest PCE for thin film tandem solar cells and has doubled the previous record for the perovskite/CIGS monolithic tandem device structure.

### REFERENCES AND NOTES

(1) C. H. Henry, Limiting efficiencies of ideal single and multiple energy gap terrestrial solar cells. J. Appl. Phys. 51, 4494-4500 (1980).
(2) A. Brown, M. A. Green, Limiting efficiency for current-constrained two-terminal tandem cell stacks. Prog. Photovolt: Res. Appl. 10, 299-307 (2002).
(3) J. Y. Kim, K. Lee, N. E. Coates, D. Moses, T. Q. Nguyen, M. Dante, A. J. Heeger, Efficient Tandem Polymer Solar Cells Fabricated by All-Solution Processing. Science 317, 222-225 (2007).
(4) S. Albrecht, M. Saliba, J. P. C. Baena, F. Lang, L. Kegelmann, M. Mews, L. Steier, A. Abate, J. Rappich, L. Korte, R. Schlatmann, M. K. Nazeeruddin, A. Hagfeldt, M. Gratzel, B. Rech, Monolithic perovskite/silicon-heterojunction tandem solar cells processed at low temperature. Energy Environ. Sci. 9, 81-88 (2016).
(5) G. E. Eperon, T. Leijtens, K. A. Bush, R. Prasanna, T. Green, J. T. Wang, D. P. McMeekin, G. Volonakis, R. L. Milot, R. May, A. Palmstrom, D. J. Slotcavage, R. A. Belisle, J. B. Patel, E. S. Parrott, R. J. Sutton, W. Ma, F. Moghadam, B. Conings, A. Babayigit, H. Boyen, S. Bent, F. Giustino, L. M. Herz, M. B. Johnston, M. D. McGehee, H. J. Snaith, Perovskite-perovskite tandem photovoltaics with optimized bandgaps. Science 10.1126/science.aaf9717 (2016).
(6) K. A. Bush, A. F. Palmstrom, Z. J. Yu, M. Boccard, R. Cheacharoen, J. P. Mailoa, D. P. McMeekin, R. L. Z. Hoye, C. D. Bailie, T. Leijtens, I. M. Peters, M. C. Minichetti, N. Rolston, R. Prasanna, S. Sofia, D. Harwood, W. Ma, F. Moghadam, H. J. Snaith, T. Buonassisi, Z. C. Holman, S F. Bent, M. D. McGehee, 23.6%-efficient monolithic perovskite/silicon tandem solar cells with improved stability. Nat. Energy 2, 17009 (2017).
(7) J. Werner, C.-H. Weng, A. Walter, L. Fesquet, J. P. Seif, S. D. Wolf, B. Niesen, C. Ballif, Efficient Monolithic Perovskite/Silicon Tandem Solar Cell with Cell Area >1 cm². J. Phys. Chem. Lett. 7, 161-166 (2016).
(8) C. D. Bailie, M. D. McGehee, High-efficiency tandem perovskite solar cells. MRS Bull. 40, 681-685 (2015).
(9) J. Kim, Z. Hong, G. Li, T. Song, J. Chey, Y. S. Lee, J. You, C. C. Chen, D. K. Sadana, Y. Yang, 10.5% efficient polymer and amorphous silicon hybrid tandem photovoltaic cell. Nat. Commun. 6, 6391 (2015).
(10) S. Mathew, A. Yella, P. Gao, R. Humphry-Baker, B. F. E. Curchod, N. Ashari-Astani, I. Tavernelli, U. Rothlisberger, M. K. Nazeeruddin, M. Grätzel, Dye-sensitized solar cells with 13% efficiency achieved through the molecular engineering of porphyrin sensitizers. Nat. Chem. 6, 242-247 (2014).
(11) L. Dou, J. You, Z. Hong, Z. Xu, G. Li, R. A. Street, Y. Yang, 25th Anniversary Article: A Decade of Organic/Polymeric Photovoltaic Research. Adv. Mater. 25, 6642-6671 (2013).
(12) M. Graetzel, R. A. J. Janssen, D. B. Mitzi, E. H. Sargent, Materials interface engineering for solution-processed photovoltaics. Nature 488, 304-312 (2012).
(13) A. Chinlă, P. Reinhard, F. Pianezzi, P. Bloesch, A. R. Uhl, C. Fella, L. Kranz, D. Keller, C. Gretener, H. Hagendorfer, D. Jaeger, R. Erni, S. Nishiwaki, S. Buecheler, A. N. Tiwari, Potassium-induced surface modification of Cu(In,Ga)Se₂ thin films for high-efficiency solar cells. Nat. Mater. 12, 1107-1111 (2013).
(14) NREL, Best Research Cell Efficiencies https://www.nrel.gov/pv/assets/images/efficiency-chart.png (2017).
(15) W. S. Yang, J. H. Noh, N. J. Jeon, Y. C. Kim, S. Ryu, J. Seo, S. I. Seok, High-performance photovoltaic perovskite layers fabricated through intramolecular exchange. Science 348, 1234-1237 (2015).
(16) S. D. Stranks, P. K. Nayak, W. Zhang, T. Stergiopoulos, H. J. Snaith, Formation of Thin Films of Organic—Inorganic Perovskites for High-Efficiency Solar Cells. Angew. Chem., Int. Ed. 54, 3240-3248 (2015).
(17) H. S. Jung, N.-G. Park, Perovskite Solar Cells: From Materials to Devices. Small 11, 10-25 (2015).
(18) M. D. McGehee, Materials science: Fast-track solar cells. Nature 501, 323-325 (2013).
(19) P. Jackson, R. Wuerz, D. Hariskos, E. Lotter, W. Witte, M. Powalla, Effects of heavy alkali elements in Cu(In,Ga)Se₂ solar cells with efficiencies up to 22.6%. Phys. Status Solidi Res. Lett. 10, 583-586 (2016).
(20) A. Chirilă, S. Buecheler, F. Pianezzi, P. Bloesch, C. Gretener, A. R. Uhl, C. Fella, L. Kranz, J. Perrenoud, S. Seyrling, R. Verma, S. Nishiwaki, Y. E. Romanyuk, G. Bilger, A. N. Tiwari, Highly efficient Cu(In,Ga)Se2 solar cells grown on flexible polymer films. Nat. Mater. 10, 857-861 (2011).
(21) T. K. Todorov, O. Gunawan, T. Gokmen, D. B. Mitzi, Solution-processed Cu(In,Ga)(S,Se)₂ absorber yielding a 15.2% efficient solar cell. Prog. Photovolt: Res. Appl. 21, 82-87 (2013).
(22) S. Jung, S. J. Ahn, J. H. Yun, J. Gwak, D. Kim, K. Yoon, Effects of Ga contents on properties of CIGS thin films and solar cells fabricated by co-evaporation technique. Curr. Appl. Phys. 10, 990-996 (2010).
(23) D. P. McMeekin, G. Sadoughi, W. Rehman, G E Eperon, M. Saliba, M. T. Hörantner, A. Haghighimd, N. Sakai, L. Korte, B. Rech, M. B. Johnston, L. M. Herz, H. J. Snaith, A mixed-cation lead mixed-halide perovskite absorber for tandem solar cells. Science 351, 151-155 (2016).
(24) N. J. Jeon, J. H. Noh, W. S. Yang, Y. C. Kim, S. Ryu, J. Seo, S. I. Seok, Compositional engineering of perovskite materials for high-performance solar cells. Nature 517, 476-480 (2015).
(25) J. W. Lee, D. H. Kim, H. S. Kim, S. W. Seo, S. M. Cho, N. G. Park, Formamidinium and cesium hybridization for photo- and moisture-stable perovskite solar cell. Adv. Energy Mater. 5, 1501310 (2015).
(26) R. E. Beal, D. J. Slotcavage, T. Leijtens, A. R. Bowring, R. A. Belisle, W. H. Nguyen, G. F. Burkhard, E. T. Hoke, M. D. McGehee, Cesium Lead Halide Perovskites with Improved Stability for Tandem Solar Cells. J. Phys. Chem. Lett. 7, 746-751 (2016).
(27) T. J. Coutts, J. S. Ward, D. L. Young, K. A. Emery, T. A. Gessert, R. Noufi, Critical issues in the design of polycrystalline, thin-film tandem solar cells. Prog. Photovolt: Res. Appl. 11, 359-375 (2003).
(28) F. Meillaud, A. Shah, C. Droz, E. Vallat-Sauvain, C Miazza, Efficiency limits for single junction and tandem solar cells. Sol. Energy Mater. Sol. Cells 90, 2952-2959 (2006).
(29) L. Kranz, A. Abate, T. Feurer, F. Fu, E. Avancini, J. Lockinger, P. Reinhard, S. M. Zakeeruddin, M. Grätzel, S. Buecheler, A. N. Tiwari, High-Efficiency Polycrystalline Thin Film Tandem Solar Cells. J. Phys. Chem. Lett. 6, 2676-2681 (2015).
(30) C. Zuo, H. J. Bolink, H. Han, J. Huang, D. Cahen, L. Ding, Advances in Perovskite Solar Cells. Adv. Sci. 3, 1500324 (2016).
(31) A. Guchhait, H. A. Dewi, S. W. Leow, H. Wang, G. Han, F. B. Suhaimi, S Mhaisalkar, L. H. Wong, N. Mathews, Over 20% Efficient CIGS—Perovskite Tandem Solar Cells. ACS Energy Lett. 2, 807-812 (2017).
(32) F. Fu, T. Feurer, T. P. Weiss, S. Pisoni, E. Avancini, C. Andres, S. Buecheler, A. N. Tiwari, High-efficiency inverted semi-transparent planar perovskite solar cells in substrate configuration. Nat. Energy 2, 16190 (2016).
(33) T. Todorov, T. Gershon, O. Gunawan, Y. S. Lee, C. Sturdevant, L.Y. Chang, S. Guha, Monolithic Perovskite-CIGS Tandem Solar Cells via In Situ Band Gap Engineering. Adv. Energy Mater. 5, 1500799 (2015).
(34) G. W. Choia, K. Y. Lee, N. H. Kim, J. S. Park, Y. J. Seo, W. S. Lee, CMP characteristics and optical property of ITO thin film by using silica slurry with a variety of process parameters. Microelectron. Eng. 83, 2213-2217 (2006).
(35) K. Y. Lee, G. W. Choi, Y. J. Kim, Y. O. Choi, N. O. Kim, Chemical mechanical polishing characteristics of ITO thin film prepared by RF magnetron sputtering, J. Korean Phys. Soc. 60, 388-392 (2012).
(36) K. A. Bush, C. D. Bailie, Y Chen, A. R. Bowring, W. Wang, W. Ma, T. Leijtens, F. Moghadam, M. D. McGehee, Thermal and Environmental Stability of Semi-Transparent Perovskite Solar Cells for Tandems Enabled by a Solution-Processed Nanoparticle Buffer Layer and Sputtered ITO Electrode. Adv. Mater. 28, 3937-3943 (2016).
(37) Q. Wang, C. Bi, J. Huang, Doped Hole Transport Layer for Efficiency Enhancement in Planar Heterojunction Organolead Trihalide Perovskite Solar Cells. Nano Energy 15, 275-280 (2015).
(38) C. Bi, Q. Wang, Y. Shao, Y. Yuan, Z. Xiao, J. Huang, Non-wetting surface-driven high-aspect-ratio crystalline grain growth for efficient hybrid perovskite solar cells. Nat. Commun. 6, 7747 (2015).
(39) Y. Shao, Y. Yuan, J. Huang, Correlation of energy disorder and open-circuit voltage in hybrid perovskite solar cells. Nat. Energy 1, 15001 (2016).
(40) J. Xu, A. Buin, A. H. Ip, W. Li, O. Voznyy, R. Comin, M. Yuan, S. Jeon, Z. Ning, J. J. McDowell, P. Kanjanaboos, J. P. Sun, X. Lan, L. N. Quan, D. H. Kim, I. G. Hill, P. Maksymovych, Edward H. Sargent, Perovskite-fullerene hybrid materials suppress hysteresis in planar diodes. Nat. Commun. 6, 7081 (2015).
(41) Y. Li, Y. Zhao, Q. Chen, Y. Yang, Y. Liu, Z. Hong, Z. Liu, Y. T. Hsieh, L. Meng, Y. Li, Y. Yang, Multifunctional Fullerene Derivative for Interface Engineering in Perovskite Solar Cells. J. Am. Chem. Soc. 137, 15540-15547 (2015).
(42) M. Saliba, Perovskite solar cells must come of age. Science 359, 388-389 (2018).
(43) K. Domanski, E A Alharbi, A. Hagfeldt, M. Grätzel, W. Tress, Systematic investigation of the impact of operation conditions on the degradation behaviour of perovskite solar cells. Nat. Energy 3, 61-67 (2018).
(44) J. You, L. Meng, T. B. Song, T. F. Guo, Y. Yang, W. H. Chang, Z. Hong, H. Chen, H. Zhou, Q. Chen, Y. Liu, N. D. Marco, Y. Yang, Improved air stability of perovskite solar cells via solution-processed metal oxide transport layers. Nat. Nanotechnol. 11, 75-81 (2016).
(45) T. Kato, A. Handa, T Yagioka, T. Matsuura, K. Yamamoto, S. Higashi, J. L. Wu, K. F. Tai, H. Hiroi, T. Yoshiyama, T. Sakai, H. Sugimoto, Enhanced Efficiency of Cd-Free Cu(InGa)(SeS)₂ Minimodule Via (Zn, Mg)O Second Buffer Layer and Alkali Metal Post-Treatment. IEEE J. Photovolt. 7, 1773-1780 (2017).
(46) R. Kamada, T Yagioka, S. Adachi, A. Handa, K. F. Tai, T. Kato, H. Sugimoto, New World Record Cu(In,Ga)(Se,S)₂ Thin Film Solar Cell Efficiency Beyond 22%. Proc. 43rd IEEE Photovoltaic Specialists Conf. (PVSC), 1287-1291 (2016).
(47) K. Kato, Cu(In,Ga)(Se,S)₂ solar cell research in Solar Frontier: Progress and current status. Jpn. J. Appl. Phys. 56, 04CA02 (2017).

The embodiments illustrated and discussed in this specification are intended only to teach those skilled in the art how to make and use the invention. In describing embodiments of the invention, specific terminology is employed for the sake of clarity. However, the invention is not intended to be limited to the specific terminology so selected. The above-described embodiments of the invention may be modified or varied, without departing from the invention, as appreciated by those skilled in the art in light of the above teachings. It is therefore to be understood that, within the scope of the claims and their equivalents, the invention may be practiced otherwise than as specifically described.

1. A monolithic tandem photovoltaic cell, comprising:
a first electrode;
a CIGS light absorption section on said first electrode;
an interconnecting layer on said CIGS light absorption section; and
a perovskite light absorption section on said inter-connecting layer,
wherein said interconnecting layer has a polished surface on which said perovskite light absorption section is formed,
wherein said interconnecting layer provides an electrically conducting and optically transparent connection between said CIGS light absorption section and said perovskite light absorption section.

2. The monolithic tandem photovoltaic cell according to claim 1, wherein said polished surface of said interconnecting layer has a maximum vertical distance (VD) less than 250 nm.

3. The monolithic tandem photovoltaic cell according to claim 1, wherein said polished surface of said interconnecting layer has a maximum vertical distance (VD) less than 100 nm.

4. The monolithic tandem photovoltaic cell according to claim 1, wherein said polished surface of said interconnecting layer has a maximum vertical distance (VD) in the range of 100 nm to 5 nm.

5. The monolithic tandem photovoltaic cell according to claim 1, wherein said polished surface of said interconnecting layer has a maximum vertical distance (VD) in the range of 40 nm to 10 nm.

6. The monolithic tandem photovoltaic cell according to claim 1, wherein said interconnecting layer is an ITO layer between 200 nm and 400 nm thick.

7. The monolithic tandem photovoltaic cell according to claim 1, wherein said interconnecting layer is an ITO layer about 300 nm thick.

8. The monolithic tandem photovoltaic cell according to claim 1, wherein said perovskite light absorption section comprises a hole transport layer formed on said interconnecting layer,
wherein said hole transport layer comprises PTAA doped with at least one of F4-TCNQ and TPFB.

9. The monolithic tandem photovoltaic cell according to claim 1, wherein said perovskite light absorption section comprises a hole transport layer formed on said interconnecting layer,
wherein said hole transport layer comprises PTAA doped with between 0.5 wt % to 2 wt % of F4-TCNQ and with between 5 wt % to 15 wt % of TPFB.

10. The monolithic tandem photovoltaic cell according to claim 1, wherein said perovskite light absorption section comprises a hole transport layer formed on said interconnecting layer,
wherein said hole transport layer comprises PTAA doped with about 1 wt % of F4-TCNQ and with about 10 wt % of TPFB.

11. The monolithic tandem photovoltaic cell according to claim 1, wherein said first electrode is formed on a substrate.

12. The monolithic tandem photovoltaic cell according to claim 11, wherein said substrate is a flexible substrate.

13. The monolithic tandem photovoltaic cell according to claim 11, wherein said substrate is a soda-lime glass substrate.

14. The monolithic tandem photovoltaic cell according to claim 1, wherein said first electrode is Mo.

15. The monolithic tandem photovoltaic cell according to claim 1, wherein said CIGS light absorption section comprises a CIGS absorber layer and a CdS layer deposited on said CIGS absorber layer.

16. The monolithic tandem photovoltaic cell according to claim 15, wherein said CIGS light absorption section comprises an i-ZnO layer formed on said CdS layer and a BZO layer formed on said i-ZnO layer.

17. The monolithic tandem photovoltaic cell according to claim 1, wherein said perovskite light absorption section comprises a PCBM layer formed on a perovskite absorber layer, a layer of ZnO nanoparticles formed on said PCBM layer, and an ITO layer formed on said layer of ZnO nanoparticles, said ITO layer being said second electrode.

18. The monolithic tandem photovoltaic cell according to claim 1, further comprising an anti-reflection coating formed on said second electrode.

19. The monolithic tandem photovoltaic cell according to claim 18, wherein said anti-reflection coating is a MgF₂ anti-reflection coating.

20. The monolithic tandem photovoltaic cell according to claim 1, wherein said interconnecting layer is substantially optically transparent to light within an absorption band of said CIGS light absorption section.

21. A method of producing a monolithic tandem photovoltaic cell, comprising:
providing a first electrode on a substrate;
producing a CIGS light absorption section on said first electrode;
depositing an interconnecting layer on said CIGS light absorption section;
polishing said interconnecting layer; and
producing a perovskite light absorption section on said inter-connecting layer,
wherein said interconnecting layer provides an electrically conducting and optically transparent connection between said CIGS light absorption section and said perovskite light absorption section.

22. The method according to claim 21, wherein said polishing said interconnecting layer provides a surface of said interconnecting layer has a maximum vertical distance (VD) less than 250 nm.

23. The method according to claim 21, wherein said polishing said interconnecting layer provides a surface of said interconnecting layer has a maximum VD less than 100 nm.

24. The method according to claim 21, wherein said polishing said interconnecting layer provides a surface of said interconnecting layer has a maximum VD in the range of 100 nm to 5 nm.

25. The method according to claim 21, wherein said polishing said interconnecting layer provides a surface of said interconnecting layer has a maximum VD in the range of 40 nm to 10 nm.

26. The method according to claim 21, wherein said depositing said interconnecting layer deposits an ITO layer about 300 nm thick.

27. The method according to claim 21, wherein said depositing said interconnecting layer deposits an ITO layer of between 200 nm to 400 nm thick.

28. The method according to claim 21, wherein said producing said perovskite light absorption section on said inter-connecting layer comprises depositing a hole transport layer on said interconnecting layer and doping said hole transport layer to increase hole conduction thereof.
